(19) United States
(12) Patent Application Publication
(10) Pub. No.: US 2025/0363612 A1
(43) Pub. Date: Nov. 27, 2025

(54) CONTROL SYSTEM FOR A PRINTING APPARATUS

(71) Applicant: EKRA Automatisierungssysteme GmbH, Bönnigheim (DE)

(72) Inventors: Torsten VEGELAHN, Sternenfels (DE); Sebastian TEPNER, Bönnigheim (DE)

(21) Appl. No.: 19/216,969

(22) Filed: May 23, 2025

(30) Foreign Application Priority Data
May 27, 2024 (DE) 10 2024 114 864.0

(51) Int. Cl. G06T 7/00; B41F 15/08; B41F 15/12; B41F 15/36; B41F 15/44; B41F 33/00

(52) U.S. Cl. CPC G06T 7/0004; B41F 15/0813; B41F 15/12; B41F 15/36; B41F 15/44; B41F 33/00; G06T 2200/24; G06T 2207/20081; G06T 2207/30108

(57) ABSTRACT

A control system for a printing apparatus for printing in particular flat substrates, with a rack, on which a receptacle for a printing template, in particular printing screen or printing stencil, is arranged, with a camera device, which is assigned to the receptacle, and with a user interface for inputting and/or obtaining information. What is provided is an evaluation device, which is connected to the camera device, in order to receive at least one image of the printing template detected by the camera device, wherein the evaluation device is formed to classify the printing template as being reusable or as being non-reusable as a function of the received image.

### CROSS REFERENCE TO RELATED APPLICATION

This application claims the benefit of German Application No. 10 2024 114 864.0, filed on May 27, 2024, the entire disclosure of which is hereby incorporated herein by reference.

### FIELD OF THE INVENTION

The present invention relates to a control system for a printing apparatus for printing in particular flat substrates, with a rack, on which a receptacle for a printing template, in particular printing screen or printing stencil, is arranged, with a camera device, which is assigned to the receptacle, and with a user interface for inputting and/or obtaining information.

The invention furthermore relates to a printing system for printing in particular flat substrates, with a printing table and a printing apparatus assigned to the printing table, with a receptacle, which is formed to hold a printing template, in particular printing screen or printing stencil, for the printing apparatus, and with a transport apparatus for feeding and discharging the printing template.

The invention further relates to a method for operating the control system as well as a method for operating the printing system.

### BACKGROUND OF THE INVENTION

Control systems and printing apparatuses of the above-mentioned type are already known from the prior art. Modern printing systems work in such a way that printing templates in the form of printing screens or printing stencils are automatically fed to a printing apparatus by means of a feeding and discharge device, in order to then perform a printing process by means of these printing templates. For this purpose, the printing apparatus generally has a receptacle, in which the respective printing template can be arranged and can be fastened. The receptacle is thereby often formed so as to be capable of being displaced, in order to optimally provide for an alignment of the printing template in relation to the substrate to be printed. Modern printing apparatuses thereby also have a control system with a camera device, which is assigned to the receptacle, in order to detect the printing template located therein and in particular the alignment and position thereof. The substrate, which generally lies below the printing template, is additionally often also detected by means of the camera device, which can have one or several cameras, in order to determine the alignment of printing template and substrate relative to one another by means of image evaluation, in order to then optimally align printing template and substrate relative to one another in an automated manner as a function of the detected alignment. After alignment has taken place, a printing medium is pushed through the printing template, for example by means of one or several doctor blades of a doctor blade device and is thus applied to the substrate. The printed substrate is subsequently separated from the printing template and is removed from the printing apparatus or from the printing table of the printing apparatus, respectively. Due to the fact that this process is repeated again and again, the printing template is also exposed to a wear and has to be replaced when the wear has exceeded a permissible level, in order to avoid misprints. Printing template and doctor blade have to additionally be cleaned routinely, often several times a day, in order to avoid unwanted residues, contaminations or damages, which could impact the printing result.

### BRIEF SUMMARY OF THE INVENTION

The invention is based on the object of creating an improved control system, which in particular monitors the state of a printing template.

The object on which the invention is based is solved by means of a control system with the features of claim 1. This control system has the advantage that already available means of the control system are now used to check the printing template and to classify whether the detected printing template can still be used, or whether it has to be fed to a cleaning, for example, in order to be able to still use it, or whether it has to be excluded completely from the production process because it is contaminated or damaged in such a way that a further use of the printing template would definitely lead to misprints. For this purpose, the control system according to the invention provides that it classifies the printing template as being reusable or as being non-reusable. For this purpose, the control system has an evaluation device, which is connected to the camera device, in order to receive at least one image of the printing template detected by the camera device, wherein the evaluation device is formed to classify the printing template as being reusable or as being non-reusable as a function of the received image, in particular by means of image evaluation, preferably AI-supported image evaluation. The already existing camera device is thus used to detect at least one image of the printing template and to feed it to the evaluation device. The evaluation device performs an image evaluation of the detected printing template, in order to detect, for example, the degree of contamination of the printing template or damages to the printing template. If a degree of contamination is detected, which exceeds an in particular specified critical value, the printing template is classified as being non-reusable. In this context, the term “non-reusable” thereby means that the printing template cannot or should not be reused directly at least initially. This does not rule out that the printing template can be reused after a cleaning process of the printing template. In this case, the classification only relates to the direct reuse of the printing template without intermediate steps. If the printing template is classified as being non-reusable, it is transferred, for example, to a cleaning station, is marked as being non-reusable and/or is excluded from the further production process as a whole. The decision between the feeding to a cleaning system and the complete exclusion thereby preferably takes place in particular as a function of the level of the detected contamination and/or damage.

The evaluation device preferably has an artificial intelligence and/or a neuronal network, by means of which the image evaluation of the received image of the printing template is carried out. The evaluation device is preferably trained or can be trained with the help of training datasets, which is in particular prepared prior to the startup of the control system in that printing templates are detected by means of the camera device and are displayed to a user. The user is preferably given the option of marking points of the printing template, which are contaminated or damaged and to specify the level of contamination or damage. Together with the data input by the user, the detected image is stored as training dataset and is used in a training process to train the AI or the neuronal network in such a way that an automated classification, as it has been described above, takes place in the later usage.

The evaluation device is preferably connected to the user interface, in order to report the result of the classification. After an image evaluation has taken place, the user is thus informed as to whether the printing template was classified as being reusable or non-reusable. In addition, the detected points, at which the printing template is contaminated and/or damaged, are optionally displayed to the user, so that the user can manually override the automatically brought about classification if necessary and can use the printing template again, for example contrary to the recommendation of the control system or can mark it as being reusable or can mark it as being non-reusable, respectively.

The user interface thereby preferably has input means, which make it possible for the user to classify a printing template, the image of which is displayed by the display, as being reusable or as being non-reusable, in order to create a training dataset. By means of the input of the user, a new training dataset is thus created, which is stored in the control system. The control system is hereby also trained and improved further during ongoing operation, so that the control system continues to learn and the classification is steadily improved. The input means is preferably formed as keyboard or touch-sensitive screen.

It is furthermore preferably provided that the evaluation device has at least one nonvolatile memory, in which training datasets are stored or can be stored. The above-described training datasets are thus advantageously stored permanently and are available for further training runs at any time.

Particularly preferably, a feeding and discharge device is assigned to the receptacle, by means of which feeding and discharge device a printing template can be feed to the receptacle and by means of which a printing template can be removed from the receptacle. An automated feeding and discharging of the printing templates into the control system or out of the control system, respectively, is made possible thereby. A fully-automated integration of the control system into a printing system is ensured in an advantageous manner thereby, so that, for example during replacement, a printing stencil in a printing apparatus can be classified or is classified, respectively, automatically by means of the control system after a printing was performed.

The control system preferably has a control unit, which controls at least the feeding and discharge device and which is formed to communicate with the evaluation device. The control unit in particular controls the feeding and discharge device to convey the analyzed printing template either back to the printing means, to a cleaning device or to a waste storage through the discharge direction as a function of the classification of the analyzed printing template.

The evaluation device is furthermore preferably formed to mark regions of the printing stencil, which have been qualified as being critical, in such a way that the marking is displayed by the display together with the printing stencil. As already mentioned above, it is hereby possible to the user in an advantageous manner to check the result of the classification of the evaluation device himself/herself and to change it if necessary.

The printing system according to the invention with the features of claim 11 is characterized by the control system according to the invention. The advantages, which have already been mentioned above, result hereby. The control system is thereby preferably integrated into the printing system in such a way that the receptacle of the printing apparatus forms the receptacle of the control system, so that the classification of the printing template can take place in the printing apparatus itself and so that the space requirement for the control system is reduced significantly thereby. According to an alternative embodiment, the receptacle of the control system is formed separately from the receptacle of the printing apparatus, in order to be able to carry out the classification independently of the printing apparatus. This results in the advantage that the printing apparatus can still be used while carrying out the classification.

The printing system furthermore preferably has a transport system for feeding and discharging the substrates to or from the printing table, respectively, in order to ensure an automated printing process. The advantageous feeding and discharge apparatus for the printing templates is formed as feeding or discharge device for feeding and discharging the printing templates into the printing apparatus or as additional feeding and discharge device of the control system for feeding and discharging the printing template into the receptacle of the control system, depending on whether the control system and the printing apparatus use the same receptacle or different receptacles.

The printing apparatus further preferably has a doctor blade device, by means of which printing mass can be applied to the substrate on the printing table by means of the printing template.

The method according to the invention for operating the control system with the features of claim 14 is characterized in that at least one image of the printing template is detected by means of the camera device and that the detected image is classified as being reusable or as being non-reusable by means of an evaluation device as a function of the detected image of the printing template. The advantages, which have already been mentioned above, result hereby. An artificial intelligence and/or a neuronal network is preferably used for the image evaluation, which are trained for this purpose with training datasets beforehand, as described above. The artificial intelligence and/or the neuronal network are preferably trained further during the ongoing operation of the control system, in that the user is given the option of checking the result of the classification and of overriding it if necessary, as it has already been described above.

The method according to the invention for operating the printing system with the features of claim 15 is characterized by the method according to the invention for operating the control system. The advantages, which have already been mentioned above, result.

### BRIEF DESCRIPTION OF THE DRAWINGS

Further advantages and preferred features and feature combinations follow in particular from that, which has been described above as well as from the claims. The invention will be explained in more detail below on the basis of the drawing, for the purpose of which:

FIG. 1 shows an advantageous control system and

FIG. 2 shows an advantageous printing system, in each case in a simplified perspective illustration.

### DESCRIPTION OF EXAMPLE EMBODIMENTS

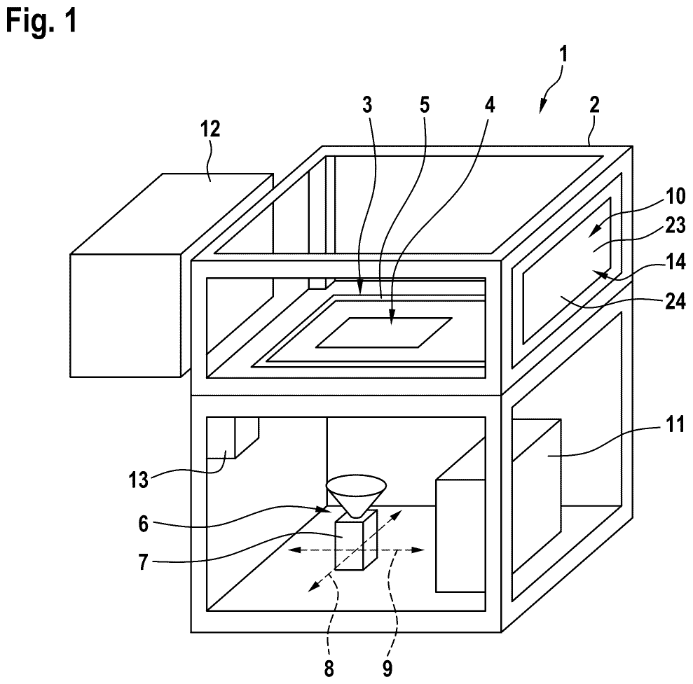

FIG. 1 shows, in a simplified perspective illustration, an advantageous control system for printing stencils. The control system 1 has a rack 2 or a frame, on which a receptacle 3 for printing stencils is arranged. The receptacle 3 is formed, for example, in such a way that the printing template 4 with a frame 5 can be placed in such a way that the stencil shape is freely accessible. The printing template is in particular a printing stencil or a printing screen. In the present case, the receptacle 3 is in particular formed as support, onto which the printing template 4 can be placed with its outer edge 5. The receptacle 3 in particular has an opening, which is smaller than the frame 5, so that the printing template 4 can be detected by means of a camera device 6, which is arranged below the receptacle 4 in or on the rack 2. In the present case, the camera device 6 has a stationary camera 7, which is assigned to the receptacle 3 in such a way that the entire printing template 4 can be detected in one image by the camera 7. According to an alternative exemplary embodiment, the camera device 6 has several cameras 7, in order to detect the entire printing template in the receptacle 3. According to a further exemplary embodiment, it is provided that even though the camera device 6 has only one camera 7, said camera can be moved, as shown in FIG. 1 by means of dashed arrows 8 and 9, by means of actuators, which are likewise present, in such a way that it can detect the entire printing template 4 in one or several images by means of its movement.

The control system 1 furthermore has a user interface 10 as well as an evaluation device 11. The evaluation device 11 is connected to the camera device 6 as well as to the user interface 10 and is formed to receive an image of the printing template 4 detected by the camera device and to classify the printing template as being “reusable” or as being “non-reusable” as a function of the received image.

For this purpose, the evaluation device 11 has an artificial intelligence, in particular an AI module and/or a neuronal network, by means of which an image evaluation of the image of the printing template provided by the camera is carried out. The image is thereby analyzed as to whether the printing template has signs of contamination or of wear, which are not suitable for a direct reuse of the printing template for a further print. It is ensured in this way that no damaged or faulty printing template is permitted into the further production.

If several cameras 7 are available, the number of the cameras 7 is preferably chosen as a function of the size of the printing template to be analyzed and/or of a desired throughput (cycle time). Several cameras shorten the image recording time and increase the lateral recording surface. A displaceable or movable camera improves the interaction and, if necessary, provides for the control of chosen regions of the printing template. The one movable camera can additionally also be used for other purposes, such as, for example, for an alignment of printing template to substrate to be printed, as will be explained in more detail further below.

The evaluation device 11 is formed to be able to detect any anomaly of the printing template, which could negatively influence the printing process. For this purpose, the AI module is trained with the help of training datasets to detect deviations in the surface finish, such as, for example, scratches, deformations, for example dents or bumps, trenches, changes to the roughness and surface coating, contaminations of the surface by printing paste or other substances, as well as blockages of the apertures or openings in the printing template. The training preferably takes place with different selected sample materials in relation to the printing stencil or the printing template, respectively, as well as in relation to the printing mass to be used, so that a ready-to-use system is available. In response to each inspection or analysis, the AI module learns more, so that a complex supervision and parameterization of the control system can be forgone.

The expected formation of the printing stencil is preferably announced to the control system 1, in that the still unused printing stencil is inspected for the first time, for example at the beginning of the process, in order to create a reference. Later during operation, the AI module or the evaluation device 11, respectively, can then determine differences compared to the reference with little effort and can determine the level of contamination and/or of wear of the printing template 4. The evaluation device 11 then classifies the printing template 4 as being reusable or as being non-reusable as a function of the level of contamination and/or wear. The evaluation device 11 hereby initially only decides whether or not the printing stencil 4 can be reused immediately. In the event that the printing stencil 4 is classified as being “non-reusable”, a decision is thus preferably additionally made as to whether the printing stencil can be or is to be fed to a cleaning process, in order to make the printing template 4 reusable again, or whether a cleaning process cannot lead to the desired result due to the wear or contamination because the printing template has been damaged severely, for example, in order to then additionally classify the non-reusable printing template as not being cleanable or as waste, so that it is removed from the production process as a whole.

In this regard, the evaluation device 11 preferably classifies the analyzed printing template 4 as being “reusable”, as being “non-reusable but cleanable” or as “permanently non-reusable”.

A discharge and feeding device 12, by means of which the printing stencils 4 can be fed to the receptacle 3 in an automated manner and can be removed from the latter, is optionally assigned to the control system 1. For example, the feeding and discharge device 12 is formed to remove the printing stencil 4 from the receptacle 3 and, provided that it was classified as being reusable, feed it to a printing apparatus for use, or, if the printing stencil was classified as being non-reusable, to feed the printing stencil 4 to a cleaning device or to a waste storage. For this purpose, the feeding and discharge device 12 is expediently connected to the evaluation device 11 and/or to a control unit 13, which operates the feeding and discharge device 12 as well as the evaluation device 11 and the user interface 10.

The user interface 10 is in particular formed as touch-sensitive screen 14, with a display 23 and a touch-sensitive input means 24, and is configured to display an image of the printing template 4, which is being analyzed, to the user and to mark contaminations and/or damages, which may have been discovered by the evaluation device 11, in such a way that the user can cross-check them easily. If the user determines that a contamination or damage was classified incorrectly by the evaluation device 11, the user can override this result of the evaluation device 11 by means of an input at the user interface 10 and can thus classify, for example, a printing stencil, which the evaluation device 11 classified as being non-reusable, as being reusable and can thus override the result of the evaluation device 11 as a whole, so that the printing template 4 can be fed to a further printing process. The evaluation device 11 is preferably formed to register the inputs made by the user through the user interface 10 and to store them as training dataset together with the image of the printing template 4, in order to further optimize the intelligence or decision clarity of the evaluation device 11, respectively.

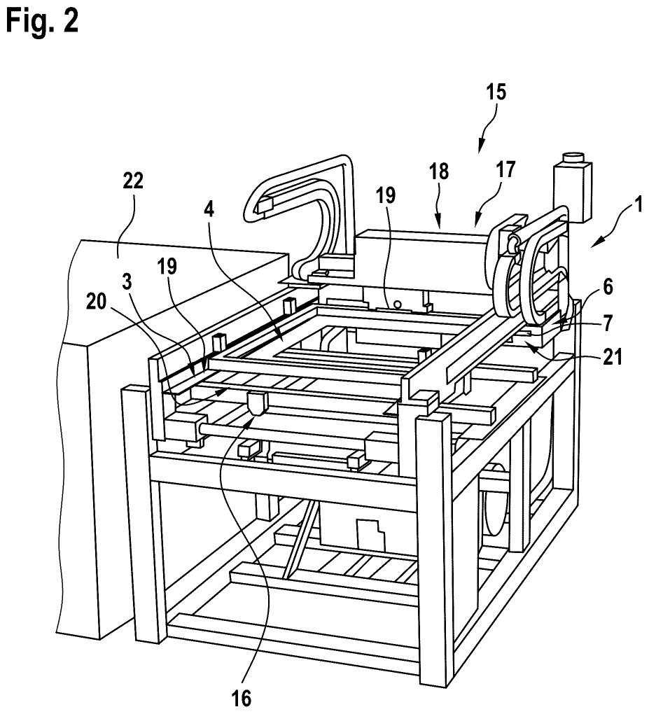

FIG. 2 shows, in a simplified perspective illustration, a printing system 15 with a printing table 16, to which a printing apparatus 17 is assigned. The printing apparatus 17 in particular has a doctor blade device 18, with at least one displaceable doctor blade 19. The printing apparatus 17 furthermore has a receptacle 19 for a printing template, in particular printing screen or stencil, as described above, which lies above the printing table 16. The printing system 15 furthermore has a transport system 20, by means of which substrates to be printed, in particular flat substrates, such as printed circuit boards, wafers or circuit boards, can be fed to the printing table 16 and can be removed from it.

In addition, the above-described control system 1 is integrated into the printing apparatus 17. For this purpose, the receptacle 19 forms the above-described receptacle 3 of the control system 1. The printing apparatus 17 furthermore has a camera device 21, which is formed to be moved between a printing template 4 arranged on the receptacle 3 and the substrate to be printed on the printing table 16, in order to detect the alignment of printing template 4 and substrate relative to one another in particular with the help of markings or fiducials (register marks), in order to subsequently move printing table 16 and/or a the receptacle 19 or the printing template 4, respectively, and/or the substrate by means of controlling actuators provided for this purpose in such a way that the alignment of printing template 4 to substrate is adapted, in particular optimized.

In this case, the camera 21 also serves as the camera 7 of the camera device 6 of the control system 1, so that it serves for a further function, namely for the classification of the printing template 4, which is located on the receptacle 3.

The control system 1 is thus advantageously integrated into the printing apparatus 17 and a printing system 15 is offered, which offers an automatic printing of substrates as well as an automated control and classification of used printing templates. Preferably, the control unit formed as part of the printing apparatus 17 or supplements a control device of the printing apparatus 17 in order to control the total operation of the printing system 15.

A cleaning device 22, to which printing templates 4 classified as being “non-reusable and cleanable” are fed by means of the feeding and discharge device 12, is optionally assigned to the printing apparatus 15, in order to clean them there and in order to then introduce them back into the position cycle.

It is attained by means of the control system 1 that defective or highly worn and or contaminated printing templates, which have, for example, blocked holes or damaged contours, are not used for the printing again and are instead cleaned in an automated manner or are permanently removed from the manufacturing process. By means of the advantageous use of the training datasets and the creation of further training datasets in the ongoing operation, the control system 1 thereby continues to learn and is thus further optimized steadily.

1. A control system for a printing apparatus for printing in particular flat substrates, with a rack, on which a receptacle for a printing template, comprising a printing screen or printing stencil, is arranged, with a camera device, which is assigned to the receptacle, and with a user interface for inputting and/or obtaining information, wherein an evaluation device, which is connected to the camera device, in order to receive at least one image of the printing template detected by the camera device, wherein the evaluation device is formed to classify the printing template as being reusable or as being non-reusable as a function of the received image.

2. The control system according to claim 1, wherein the evaluation device has an artificial intelligence and/or a neuronal network.

3. The control system according to claim 1, wherein the evaluation device is connected to the user interface, in order to report the result of the classification to a user.

4. The control system according to claim 1, wherein the user interface has a display, which is formed to display the image detected by the camera device.

5. The control system according to claim 1, wherein the user interface has input means, which make it possible for a user to classify a printing template, the image of which is displayed by the display, as being reusable or as being non-reusable, in order to create a training dataset.

6. The control system according to claim 1, wherein the evaluation device) has at least one non-volatile memory, in which training datasets are stored.

7. The control system according to claim 1, wherein a feeding and discharge device is assigned to the receptacle, by means of which feeding and discharge device a printing template can be feed to the receptacle and by means of which a printing template can be removed from the receptacle.

8. The control system according to claim 1, wherein a control unit is present, which controls at least the feeding and discharge device and which is formed to communicate with the evaluation device.

9. The control system according to claim 1, wherein the camera device has at least one stationary or displaceable camera.

10. The control system according to claim 1, wherein the evaluation device is formed to mark regions of the printing template, which have been qualified as being critical, in such a way that the marking is displayed by the display together with the printing template.

11. A printing system for printing in particular flat substrates, with a printing table and a printing apparatus assigned to the printing table, with a receptacle, which is formed to hold a printing template, comprising a printing screen or printing stencil, for the printing apparatus, and with a feeding and discharge device for feeding and discharging a printing template, comprising a control system according to claim 1.

12. The printing system according to claim 11, wherein a transport system for feeding and discharging the substrates.

13. The printing system according to claim 11, wherein the printing apparatus has a doctor blade device.

14. A method for operating the control system according to claim 1, wherein at least one image of the printing template is detected by means of the camera device, and that the detected image is classified as being reusable or as being non-reusable by means of an evaluation device as a function of the detected image of the printing template.

15. A method for operating the printing system according to claim 11, wherein at least one image of the printing template is detected by means of the camera device, and that the detected image is classified as being reusable or as being non-reusable by means of an evaluation device as a function of the detected image of the printing template.
